(19) United States
(12) Patent Application Publication
(10) Pub. No.: US 2009/0017624 A1
(43) Pub. Date: Jan. 15, 2009

(54) Nodule Defect Reduction in Electroless Plating

(76) Inventors: Chih-Hung Liao, Jhudong (TW); Hung-Wen Su, Jhubei (TW); Chun-Chieh Lin, Taichung (TW)

Correspondence Address: SLATER & MATSIL, L.L.P., 17950 PRESTON ROAD, SUITE 1000, DALLAS, TX, 75252, US

(21) Appl. No.: 11/775,113

(22) Filed: Jul. 9, 2007

(51) Int. Cl. H01L 21/441

(52) U.S. Cl. 438/678; 257/E21.477

(57) ABSTRACT

An electroless plating method and the apparatus for performing the same are provided. The method includes providing a plating solution; contacting a front surface of the wafer with the plating solution; and incurring a plating reaction substantially simultaneously on an entirety of the front surface of the wafer. The step of incurring a plating reaction substantially simultaneously includes lift-dispense electroless plating and face-down immersion.

### TECHNICAL FIELD

This invention is related generally to the formation of integrated circuits, and more particularly to electroless plating processes.

### BACKGROUND

A commonly used method for forming metal lines and vias is known as “damascene.” Generally, this method involves forming an opening in a dielectric layer, which separates the vertically spaced metallization layers. The opening is typically formed using conventional lithographic and etching techniques. After the formation, the opening is filled with copper or copper alloys to form a via or a trench. Excess metal material on the surface of the dielectric layer is then removed by chemical mechanical polish (CMP). The remaining copper or copper alloy forms vias and/or metal lines.

Copper is preferably used in damascene processes because of its lower resistivity. However, copper still suffers from electro migration (EM) and stress migration (SM) reliability issues as geometries continue to shrink and current densities increase.

FIG. 1 illustrates a cross-sectional view of a conventional interconnect structure. Typically, in the formation process of the structure shown in FIG. 1, an opening is formed in low-k dielectric 2. Diffusion barrier layer 6 is then formed in the opening, followed by filling the opening with copper. A chemical mechanical polish (CMP) is then performed to remove excess copper, forming copper line 4 in the opening. Metal cap 8 is then formed on copper line 4. Diffusion barrier layer 6 has the function of sealing copper line 4, and hence preventing copper from diffusing into low-k dielectric layer 2. Metal cap 8 reduces the electro-migration and stress-migration. With metal cap 8, the lifetime of the interconnect structure is significantly prolonged, sometimes as long as ten times as compared to the interconnect structure having no metal cap 8. Metal cap 8 is typically formed using electroless plating.

FIG. 2 illustrates a conventional spin-coating apparatus for electroless plating metal cap 8. Wafer 12 is placed on wafer holder 14, which includes guide pins 16 for securing wafer 12. Chemical dispensing nozzle 18, which is used for dispensing plating chemicals, is connected to a chemical dispenser (not shown). Typically, the electroless plating is performed at elevated temperatures by conducting hot de-ionized (DI) water under wafer 12, wherein the backside of wafer 12 may be in direct contact with the hot DI water. In a typical design, the hot DI water is conducted to the bottom center of a wafer, and then spread to the edges, as illustrated by the arrows. In addition, the plating chemicals may be heated before they are dispensed on the surface of wafer 12.

Another electroless plating method is called batch-type immersion, in which wafer 20 is slant submerged into plating solution 22, as shown in FIG. 3, with the front surface facing up.

The conventional electroless plating methods suffer drawbacks. Since at the moment the plating occurs, the wafer is in contact with the plating solution, some of the wafer area may not be wetted sufficiently. This causes side effects such as selectivity loss and nodule defects. The selectivity loss may cause the metal cap to be formed on undesirable material, such as low-k dielectrics. As a result, line-to-line leakage currents increase, and metal lines may even be shorted. The nodule defects partially result due to the generation of free electrons in the plating solution. The electrons cause the metal to be reduced in the plating solution, instead of on the surface of wafers. As a result, metal particles are generated in the plating solution. The metal particles may be undesirably attached to the surface of the wafer, causing the shorting and the increase in line-to-line leakages. In the batch type immersion, due to the slant immersion, some portions of the wafer are in contact with plating solutions earlier than other portions, and the uniformity of the plating is thus adversely affected.

Accordingly, new interconnect structures and formation methods are needed to solve the above-discussed problems.

### SUMMARY OF THE INVENTION

In accordance with one aspect of the present invention, an electroless plating method and the apparatus for performing the same are provided. The method includes providing a plating solution; contacting a front surface of the wafer with the plating solution; and incurring a plating reaction substantially simultaneously on an entirety of the front surface of the wafer. The step of incurring a plating reaction substantially simultaneously includes lift-dispense electroless plating and face-down immersion.

In accordance with another aspect of the present invention, a method of forming an integrated circuit structure includes providing hot de-ionized (DI) water having a first temperature; placing a wafer above the hot DI water with a space separating the hot DI water and the wafer; rotating the wafer; dispensing a plating solution onto a front surface of the wafer, wherein the plating solution and the wafer are at second temperatures lower than the first temperature; and increasing a temperature of the wafer to incur a plating reaction on the wafer.

In accordance with yet another aspect of the present invention, a method of forming an integrated circuit structure includes providing a wafer; dispensing a plating solution on the wafer substantially uniformly, wherein the wafer is at a first temperature lower than a plating reaction triggering temperature; allowing the plating solution on the wafer to be soaked for a soaking time; and increasing a temperature of the wafer to a second temperature higher than the plating reaction triggering temperature.

In accordance with yet another aspect of the present invention, an integrated circuit structure includes a substrate; a first low-k dielectric layer having a first k value over the substrate; a second low-k dielectric layer on and adjoining the first dielectric layer, wherein the second dielectric layer has a second k value greater than the first k value; a metal line extending substantially from a top surface of the first low-k dielectric layer into the second low-k dielectric layer; and a metal cap on the metal line.

The embodiments of the present invention result in a substantially simultaneous plating reaction on an entirety of the wafers. In addition, the wafers may be fully wetted before the plating reaction. Adverse effects such as selectivity loss and nodule effects are thus reduced.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a semiconductor structure having a metal line in a low-k dielectric layer, wherein a metal cap is formed on the metal line;

FIG. 2 illustrates a conventional electroless plating apparatus;

FIG. 3 illustrates a batch-type electroless plating process;

FIGS. 4 through 6 are cross-sectional views of intermediate stages in the formation of a metal cap over a low-k dielectric layer, wherein a metal cap is formed on a metal line using electroless plating;

FIGS. 7 through 9 illustrate a lift-dispense plating process;

FIG. 10 through 12 illustrate a face-down immersion plating process; and

FIG. 13 illustrates experiment results.

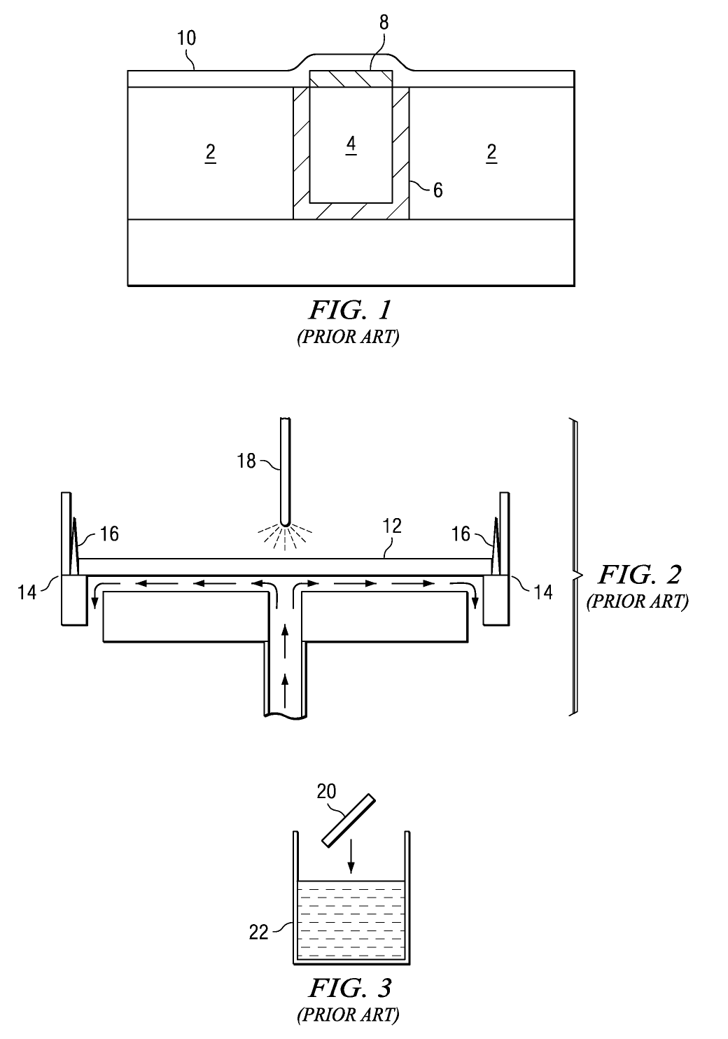

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

To reduce the non-uniformity in the electroless plating on a wafer, it is preferred that the surface of the wafer is wetted uniformly. More preferably, for different portions of the wafer surface, the reduction reaction preferably incurs simultaneously. The embodiments of the present invention provide solutions to address these preferences.

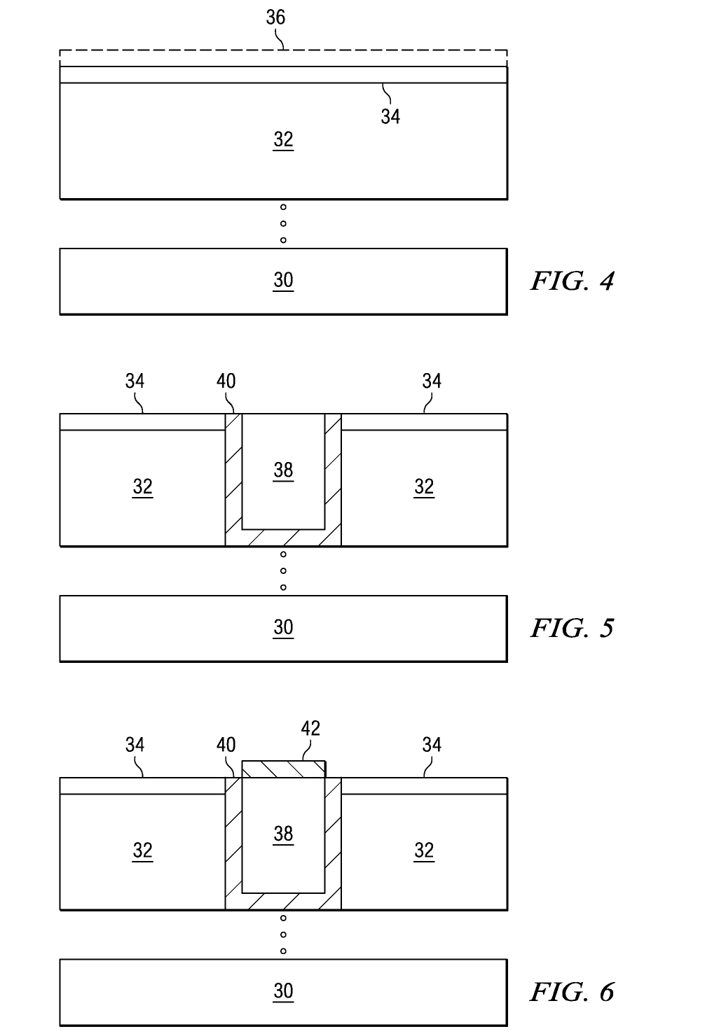

FIGS. 4 through 6 illustrate the preparation of a wafer, on which metal caps are to be electroless plated. FIG. 4 illustrates a starting structure of the wafer, which includes semiconductor substrate 30 and low-k dielectric layer 32 formed thereon. Semiconductor substrate 30 may include commonly used semiconductor materials such as silicon, silicon germanium (SiGe), and the like, and has integrated circuits (not shown) formed thereon. In the preferred embodiment, low-k dielectric layer 32 is an inter-metal dielectric (IMD) layer, preferably having a dielectric constant (k value) lower than about 3.0. Furthermore, the k value of low-k dielectric layer 32 may be lower than about 2.5 (hence is referred to as an extreme low-k dielectric layer). Low-k dielectric layer 32 may contain nitrogen, carbon, hydrogen, oxygen, fluorine, and combinations thereof. Low-k dielectric layer 32 tends to be hydrophobic, and thus has difficulty in achieving a uniform contact with the plating solution used in the subsequent plating process.

Dielectric layer 34 is formed on low-k dielectric layer 32. Preferably, dielectric layer 34 is more hydrophilic than dielectric layer 32. Dielectric layer 34 is preferably a low-k dielectric layer, with a k value of slightly greater than the k value of low-k dielectric layer 32. The exemplary k value of dielectric layer 34 may be between about 2.6 and 2.65. In an exemplary embodiment, the difference of k values of low-k dielectric layers 32 and 34 is less about 0.2, and more preferably is about 0.1. In an exemplary embodiment, dielectric layer 34 may include a similar material as, but is formed with a slightly different process conditions than, low-k dielectric layer 32. Since low-k dielectric layer 34 is thinner than low-k dielectric layer 32, with a small difference in k values, the adverse effect to the RC delay of the resulting interconnect structure is minimal. Dielectric layer 34 is preferably more hydrophilic than dielectric layer 32. In an exemplary embodiment, the contact angle between a water droplet and dielectric layer 34 is between about 30 degrees and about 70 degrees, while the contact angle between a water droplet and low-k dielectric layer 32 is between about 90 degrees and about 130 degrees. In an exemplary embodiment, dielectric layer 34 is formed using plasma enhanced chemical vapor deposition (PECVD). However, other commonly used methods such as high-density plasma CVD (HDPCVD), atomic layer CVD (ALCVD), and the like can also be used. Dielectric layer 34 may have a thickness of between about 200 Å and about 300 Å. One skilled in the art will realize, however, that the dimensions recited throughout the description are merely examples, and will scale accordingly with the scaling of integrated circuits.

FIG. 5 illustrates the formation of metal line 38 in dielectric layers 32 and 34. As is known in the art, the formation of metal line 38 includes forming a trench in dielectric layers 32 and 34, and filling the trench with metallic materials. A chemical mechanical polish may be performed to remove excess materials. Preferably, metal line 38 includes copper or copper alloys. Other metals such as tungsten, silver, aluminum, and the like may also be used. Diffusion barrier layer 40, which preferably includes titanium, titanium nitride, tantalum, tantalum nitride, and the like, is preferably formed to prevent copper from diffusing into low-k dielectric layer 32.

FIG. 6 illustrates the formation of metal cap 42 on metal line 38. Metal cap 42 preferably includes materials such as cobalt, nickel, tungsten, molybdenum, tantalum, boron, iron, phosphorus, and combinations thereof. In an exemplary embodiment, metal cap 42 includes CoWP.

In the preferred embodiment, metal cap 42 is formed using electroless plating. An advantageous feature of the present invention is that dielectric layer 34 is more hydrophilic than low-k dielectric layer 32. Therefore, the contact between the plating solution and dielectric layer 34 is more uniform than the contact between the plating solution and low-k dielectric layer 32. In the subsequent electroless plating, this in turn improves the contact between the plating solution and metal line 38. A better uniformity in the thickness of metal cap 42 can thus be achieved.

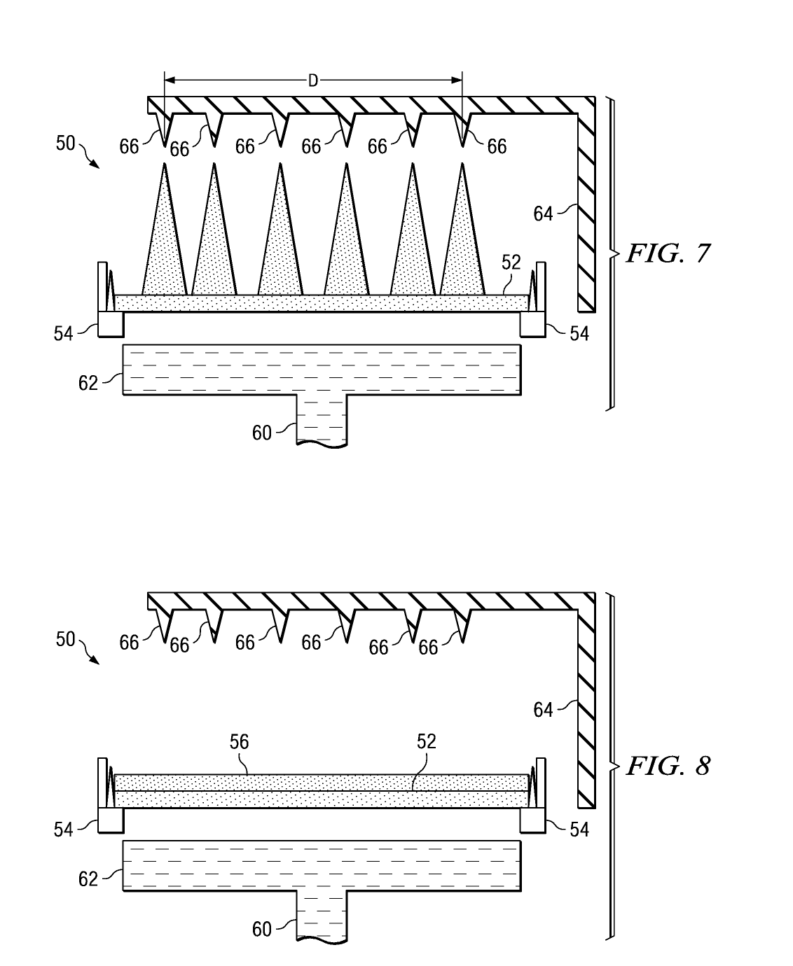

To further improve the electroless plating uniformity and reduce nodule defects, the electroless plating process is preferably modified. FIGS. 7 through 9 illustrate a first embodiment of the present invention, wherein the corresponding process is referred to as lift-dispense plating throughout the description. FIG. 7 illustrates an exemplary electroless plating apparatus 50. Wafer 52, which includes the structures to be plated, such as the structure shown in FIG. 6, is placed on wafer holder 54 with the front side of wafer 52 facing up, wherein the front side is the side to be plated. In the electroless plating processes, wafer holder 54 and wafer 52 swivel at a constant speed.

The electroless plating apparatus 50 includes pipe 60 for conducting hot de-ionized (DI) water 62, which may flow in the center-to-edge directions. The hot DI water 62 acts as a heat source for the electroless plating process. In an exemplary embodiment, hot DI water 62 has a temperature of higher than about 80° C. The backside of wafer 52 is spaced apart from hot DI water 62.

Electroless plating apparatus 50 further includes chemical dispenser 64 for dispensing plating chemicals. Chemical dispenser 64 includes nozzles 66. In an exemplary embodiment, nozzles 66 are distributed along a line over wafer 52. Distance D between two furthest nozzles may be less than, or substantially close to, a diameter of wafer 52. Preferably, nozzles 66 are such located that the coating of chemicals on wafer 52 is substantially uniform. Accordingly, nozzles 66 are symmetrical relative to the center of wafer 52.

As is known in the art, when wafer 52 swivels, the edge portions of wafer 52 travel greater distances than the center portions in a unit period of time. In addition, since wafer 52 is spinning when the plating solution is dispensed, the dispensed plating solution to the center of wafer 52 will flow to the edge. Nozzles 66 are thus distributed accordingly. In an exemplary embodiment, from over the center of wafer 52 to over the edge of wafer 52, the distances between nozzles 66 increase.

Referring to FIG. 8, in the beginning of the electroless plating process, the plating solution 56 is substantially uniformly spin-coated on wafer 52. In the meantime, wafer 52 swivels. Preferably, the plating solution 56 includes at least a metal salt (such as cobalt salt) and a reducing agent. Additionally, the plating solution may further include additives to improve the deposition of the metal, wherein the additives may include surfactants, complexing agents, pH adjusting agents, and combinations thereof. Furthermore, to achieve a more uniform wetting, a surfactant may be added.

The plating solution 56 stands on wafer 52 for a duration (referred to soaking time hereinafter) until the surface of wafer 52 is sufficiently wetted. The optimum soaking time is determined by the exposed surface materials in wafer 52. Low-k dielectric materials, which are more hydrophobic, need more time to be wetted, and hence the soaking time is longer. The spin-coated plating solution preferably has a temperature lower than a triggering temperature, wherein under the triggering temperature, there is substantially no plating reaction occurs. In an exemplary embodiment, the temperature of the plating solution is lower than about 60 degrees. More preferably, the electroless plating solution is at a room temperature, for example, 21° C. In an embodiment, more plating solution is dispensed to replenish the run-off plating solution caused by the swivel of wafer 52, either periodically, or continuously. In other embodiments, no plating solution is dispensed to replenish the run-off plating solution.

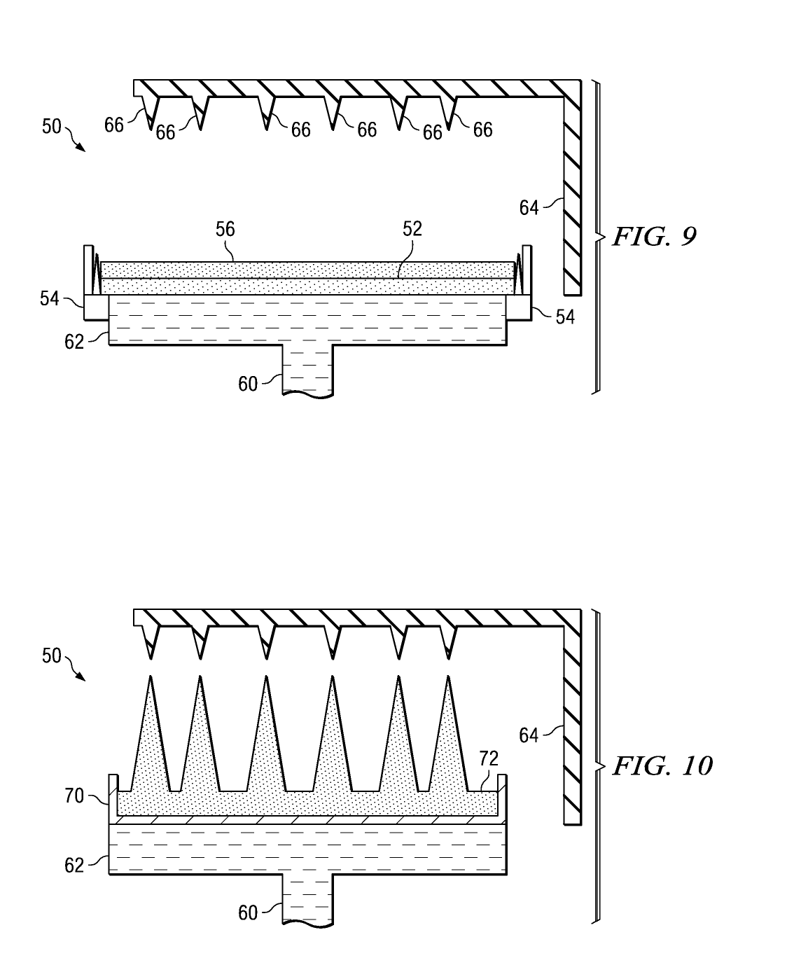

In an exemplary embodiment, the soaking time is between about 8 seconds and about 10 seconds. Wafer 52 is then lowered until the backside of wafer 52 is in contact with hot DI water 62, as is shown in FIG. 9. Accordingly, the temperatures of wafer 52 and plating solution 56 increase, and the plating reaction starts. In an exemplary embodiment, metal features such as the metal cap 42 as shown in FIG. 6 are plated due to the plating reaction. In alternative embodiments, instead of using DI hot water, the temperatures of wafer 52 and the plating solution 56 may be increased using a radiation source, for example, a lamp. An advantageous feature of this embodiment is that by the time the plating reaction starts, the surface of wafer 52 is substantially uniformly wetted. Accordingly, the likely adverse effects caused by non-uniform wetting, such as selectivity loss and nodule effect, are at least reduced, and possibly substantially eliminated. Please note that in this embodiment, although the plating solution 56 may be dispensed onto different parts of wafer 52 at different time, the plating reaction occurs substantially simultaneously.

In an embodiment, after wafer 52 is in contact with hot DI water 62, more plating solution 56 may be dispensed to ensure a sufficient supply of the plating solution 56. Alternatively, the plating solution 56 relies on the plating solution film left on the surface of wafer 52, and no plating solution 56 is dispensed after wafer 52 is in contact with hot DI water 62.

A second embodiment of the present invention is illustrated in FIGS. 10 through 12. Referring to FIG. 10, liquid holder 70 is placed on, and in contact with, hot DI water 62. Liquid holder 70 is big enough to hold a wafer. Chemical dispenser 64 dispenses plating solution 72 into liquid holder 70. In an exemplary embodiment, the temperature of the dispensed chemicals is about 75° C., slightly lower than the temperature of DI hot water 62.

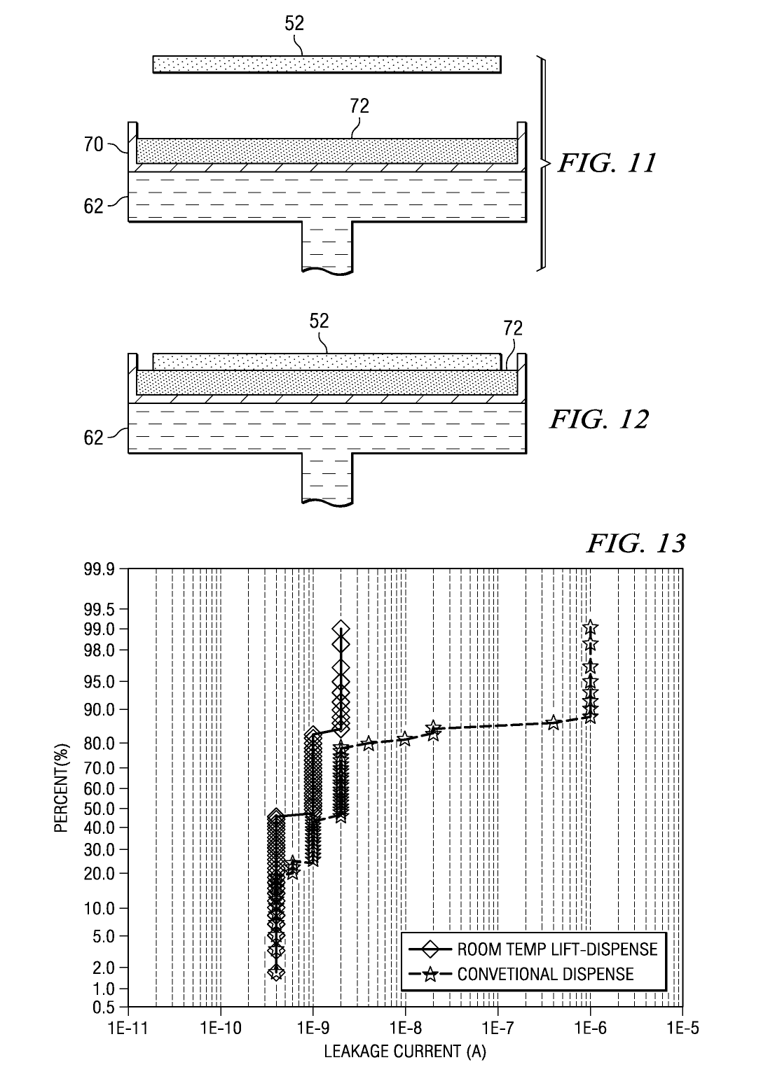

FIGS. 11 and 12 illustrate the contact of wafer 52 with plating solution 72. Wafer 52 faces down, and hence the respective plating process is referred to as face-down immersion. Preferably, wafer 52 is horizontally placed, and hence the entire front surface of wafer 52 is in contact with plating solution 72 simultaneously, resulting in a substantially simultaneous reaction. In an embodiment, only the front surface of wafer 52 is in contact with the plating solution 72, while the back surface of wafer 52 is above plating solution 72. Alternatively, the entire wafer 52 is submerged. An advantageous feature of this embodiment is that since wafer 52 faces down, the undesirably generated metal particles due to the reduction of metal ions in plating solution 72, if any, are unlikely to attach onto wafer 52 due to gravity. Accordingly, the nodule effect is reduced.

Experiment results have indicated that the embodiments of the present invention have significantly reduced line-to-line leakage currents between metal lines. FIG. 13 illustrates the cumulative percentage of samples (which are closely located metal lines with electroless-plated metal caps) as a function of leakage currents. Stars indicate the results of a first (conventional) group of samples, which are formed using a single nozzle, wherein the backsides of the sample wafers are in contact with the hot DI water when the plating chemicals are dispensed. Diamonds are the results of a second group of samples, which are formed using lift-dispense plating processes. The results indicate that the highest leakage currents in the second group of samples are about 9E-9 amps. As a comparison, a significant number of samples in the first group of samples have leakage currents as high as about 1E-06 amps, which is several orders greater than the samples in the second sample group. Visual inspection of the samples reveals that the second group of samples is substantially nodule free, while noticeable nodules are found in the first group of samples.

One skilled in the art will realize although the plating of metal caps are used as examples to explain the concept of the present invention, the embodiments of the present invention are readily available for electroless plating other metal features.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of forming an integrated circuit structure, the method comprising:
providing a wafer;
providing a plating solution;
contacting a front surface of the wafer with the plating solution; and
incurring a plating reaction substantially simultaneously on an entirety of the front surface of the wafer.

2. The method of claim 1, wherein the wafer faces up, and wherein at the time the step of contacting the front surface of the wafer with the plating solution is performed, the plating solution and the wafer are at a first temperature, and wherein the step of incurring the plating reaction comprises heating the wafer and the plating solution.

3. The method of claim 2, wherein the step of heating the wafer and the plating solution comprises contacting a backside of the wafer with hot de-ionized (DI) water, and wherein the hot DI water is at a second temperature higher than the first temperature.

4. The method of claim 3, wherein before the step of incurring the reaction, the wafer is over and spaced apart from the hot DI water.

5. The method of claim 3, wherein the first temperature is lower than about 25° C., and the second temperature is higher than about 75° C.

6. The method of claim 1, wherein the step of contacting the front surface of the wafer with the plating solution and the step of incurring the plating reaction have a time interval.

7. The method of claim 6, wherein the time interval is greater than about 8 seconds.

8. The method of claim 1, wherein the wafer faces down, and wherein the step of contacting the front surface of the wafer with the plating solution and the step of incurring the plating reaction are simultaneously performed by lowering the wafer into a horizontal position until a front side of the wafer is level and in full contact with the plating solution.

9. The method of claim 8 further comprising, before the step of contacting the front surface of the wafer with the plating solution, injecting the plating solution into a liquid holder, wherein the liquid holder comprises a bottom in contact with hot DI water.

10. The method of claim 1, wherein the step of providing the wafer comprising:
providing a substrate;
forming a first dielectric layer over the substrate;
forming a second dielectric layer on the first dielectric layer, wherein the second dielectric layer is more hydrophilic than the first dielectric layer; and
forming a metal feature in the first and the second dielectric layers, wherein at the time the step of contacting the front surface of the wafer with the plating solution is performed, the metal feature and the second dielectric layer are exposed.

11. The method of claim 1 further comprising adding a surfactant into the plating solution before the step of contacting the front surface of the wafer with the plating solution.

12. A method of forming an integrated circuit structure, the method comprising:
providing hot de-ionized (DI) water having a first temperature;
placing a wafer above the hot DI water with a space separating the hot DI water and the wafer;
rotating the wafer;
dispensing a plating solution onto a front surface of the wafer, wherein the plating solution and the wafer are at second temperatures lower than the first temperature; and
increasing a temperature of the wafer to incur a plating reaction on the wafer.

13. The method of claim 12, wherein the plating solution is dispensed from a dispenser having a plurality of nozzles.

14. The method of claim 12, wherein the first temperature is higher than a reaction triggering temperature, and the second temperatures are lower than the reaction triggering temperature.

15. The method of claim 12, wherein the step of dispensing the plating solution and the step of lowering the wafer have a time interval of greater than about eight seconds.

16. A method of forming an integrated circuit structure, the method comprising:
providing a wafer;
dispensing a plating solution on the wafer substantially uniformly, wherein the wafer is at a first temperature lower than a plating reaction triggering temperature;
allowing the plating solution on the wafer to be soaked for a soaking time; and
increasing a temperature of the wafer to a second temperature higher than the plating reaction triggering temperature.

17. The method of claim 16, wherein the step of increasing the temperature of the wafer comprises contacting a backside of the wafer with hot de-ionized (DI) water.

18. The method of claim 16, wherein the step of increasing the temperature of the wafer comprises heating the wafer using a radiation source.

19. The method of claim 16, wherein the first temperature is lower than about 25° C., and the second temperature is higher than about 75° C.
